(19) United States
(12) Patent Application Publication
(10) Pub. No.: US 2019/0353617 A1
(43) Pub. Date: Nov. 21, 2019

(54) Barkhausen Noise Sensor Comprising a Transceiver Coil

(71) Applicant: Stresstech OY, Vaajakoski (FI)

(72) Inventor: Henri Lukinmaa, Jyvaskyla (FI)

(73) Assignee: Stresstech OY, Vaajakoski (FI)

(21) Appl. No.: 15/981,974

(22) Filed: May 17, 2018

(51) Int. Cl. G01N 27/72; G01R 33/02; G01R 33/12; G01N 27/02

(52) U.S. Cl. CPC G01N 27/725; G01N 27/023; G01R 33/12; G01R 33/02

(57) ABSTRACT

A Barkhausen noise sensing device for inspecting an object made of ferromagnetic material, having a transceiver coil configured for generating an excitation magnetic field within the object and detecting a Barkhausen noise emitted by the object and a powering unit connected to the transceiver coil and connectable to a power source. The powering unit is configured for providing the transceiver coil with an Alternating Current (AC) electrical signal. Also provided is a detection unit connected to the transceiver coil for detecting an induced magnetic field emitted by the object and being indicative of the Barkhausen noise. The detection unit is configured for outputting a detection signal indicative of the detected induced magnetic field.

### TECHNICAL FIELD

The present invention relates to the field of Barkhausen noise sensors, and more particularly to Barkhausen noise sensors comprising a single coil.

### BACKGROUND

Barkhausen noise sensing method is used in the industry in non-destructive testing of surface condition of ferromagnetic components. Some applications include grinding burn detection of surface hardened parts, surface layer thickness determination and general machining quality evaluation. The Barkhausen noise emitted by objects under inspection when excited with external magnetic field is sensitive to microstructure and residual stresses of the surface layer of the object under inspection. The microstructure is related in general to hardness which is related to many properties as grain size, precipitates, dislocation density, etc. For example, ferromagnetic steel has magnetic domains which are separated by domain walls. Inside the magnetic domains, the domain atomic magnetic moments are parallel. Domains next to each other can have the same or different polarity. When an external magnetic field is introduced, the domain atoms magnetic moments gradually change to face the direction of the external magnetic field depending on the intensity of external magnetic field. These changes in magnetic polarity create a measurable magnetic signal. Domains with magnetic moments parallel to external magnetic field will grow by domain wall movement. This movement is interacting strongly with the imperfections present in the object under inspection which generates the Barkhausen noise.

Usually, Barkhausen noise testing is performed by introducing alternating magnetic field with a C-shaped yoke having coil winding over the C-shaped yoke. Alternating magnetic field can get the domain walls to move back and forth. The domain wall movement is creating a signal which can be detected by a pickup coil, which is usually located between the legs of the C-shaped yoke.

However, such a design comprising a pickup coil located between the legs of a C-shaped yoke is not adequate for inspecting objects presenting small features, such as small holes, or complicated surfaces such as surfaces provided with hypoid gear flanges.

Therefore, there is a need for an improved device and method for inspecting an object using Barkhausen noise measurement.

### SUMMARY OF THE INVENTION

According to a first broad aspect, there is provided a Barkhausen noise sensing device for inspecting an object made of ferromagnetic material, comprising: a transceiver coil configured for generating an inspection magnetic field within the object and detecting a Barkhausen noise emitted by the object; a powering unit connected to the transceiver coil and connectable to a power source, the powering unit being configured for providing the transceiver coil with an Alternating Current (AC) electrical signal, the AC electrical signal including an emission phase and a detection phase, the inspection magnetic field being generated by the transceiver coil during the emission phase and the Barkhausen noise being detected during the detection phase; and a includes detection unit connected to the transceiver coil for detecting during the detection phase an induced magnetic field emitted by the object in response to the inspection magnetic field and being indicative of the Barkhausen noise, the detection unit being configured for outputting a detection signal indicative of the detected induced magnetic field.

In one embodiment, the Barkhausen noise sensing device further includes a coil core having the transceiver coil wound therearound.

In one embodiment, the coil core has one of a U-shape, a C-shape and a cylindrical shape.

In one embodiment, the transceiver coil is embedded into the coil core.

In one embodiment, the coil core includes at least one aperture extending therethrough for receiving therein a cooling fluid.

In one embodiment, the powering unit comprises a signal generator for generating said AC electrical signal.

In one embodiment, the powering unit further includes an input low-pass filter for protecting the signal generator from a noise electrical signal generated by the transceiver coil upon detection of the induced magnetic field.

In one embodiment, the powering unit further includes an input power amplifier for amplifying the AC electrical signal generated by the signal generator.

In one embodiment, the detection unit includes a noise high pass filter for blocking the AC electrical signal.

In one embodiment, the detection unit further includes a noise amplifier for amplifying a filtered signal outputted by the noise high pass filter.

In one embodiment, the detection unit further includes at least one of an output high pass filter and an output low pass filter for filtering an amplifier signal outputted by the noise amplifier.

In one embodiment, the Barkhausen noise sensing device further includes a control flux sensor for measuring the inspection magnetic field generated by the transceiver coil.

In one embodiment, the control flux sensor includes a control flux coil.

In one embodiment, the Barkhausen noise sensing device further includes a processing unit for controlling the AC electrical signal generated by the powering unit based on the inspection magnetic field measured by the control flux sensor.

In one embodiment, the Barkhausen noise sensing device further includes an enclosing body for receiving therein at least the transceiver coil, the powering unit and the detection unit.

According to another broad aspect, there is provided a method for inspecting an object made of ferromagnetic material by Barkhausen noise measurement, comprising: providing a voltage to a transceiver coil positioned adjacent to the object during an emission phase of an Alternating Current (AC) electrical signal thereby causing the transceiver coil emits an inspection magnetic field within the object; the transceiver coil detecting an induced magnetic field emitted by the object in response to the inspection magnetic field and being indicative of the Barkhausen noise during a detection phase of the AC electrical signal; and outputting a detection signal indicative of the detected induced magnetic field.

In one embodiment, the method further includes protecting a signal generator used for generating the AC electrical signal from a noise electrical signal generated by the transceiver coil upon detection of the induced magnetic field using an input low pass filter.

In one embodiment, the method further includes amplifying the AC electrical signal before said providing the voltage to the transceiver coil.

In one embodiment, the method further includes protecting a detection unit from the AC electrical signal using a noise high pass filter.

In one embodiment, the method further includes amplifying a filtered signal outputted by the noise high pass filter, thereby obtaining an amplified signal.

In one embodiment, the method further includes filtering the amplified signal using at least one of an output high pass filter and an output low pass filter.

In one embodiment, the method further includes measuring the inspection magnetic field generated by the transceiver coil.

In one embodiment, the step of measuring the inspection magnetic field is performed using a control flux coil.

In one embodiment, the method further includes controlling the AC electrical signal based on the measured inspection magnetic field.

### BRIEF DESCRIPTION OF THE DRAWINGS

Further features and advantages of the present invention will become apparent from the following detailed description, taken in combination with the appended drawings, in which:

FIG. 1 is a block diagram of a Barkhausen noise sensing device that includes a transceiver coil, a powering unit and a detection unit, in accordance with an embodiment;

FIG. 2 is a block diagram of a Barkhausen noise sensing system that includes a transceiver coil wound around a C-shaped core, a powering unit and a detection unit, a processing unit and a computer machine, in accordance with an embodiment;

FIG. 3 is a graph illustrating exemplary excitation electrical signal, detected electrical signal, bandwidth for a low-pass filter and bandwidth for a high-pass filter;

FIG. 4 illustrates a cylindrical core to which a transceiver coil is secured, in accordance with an embodiment;

FIG. 5 illustrates a sensing unit comprises only a transceiver coil, in accordance with an embodiment;

FIG. 6 illustrates the cylindrical core of FIG. 3 to which a further coil is secured, in accordance with an embodiment;

FIG. 7 illustrates a transceiver coil embedded into a body provided with apertures for receiving a cooling fluid, in accordance with an embodiment; and

FIG. 8 is a flow chart of a method for inspecting an object made of ferromagnetic material by Barkhausen noise measurement, in accordance with an embodiment.

It will be noted that throughout the appended drawings, like features are identified by like reference numerals.

### DETAILED DESCRIPTION OF EMBODIMENTS OF THE INVENTION

FIG. 1 illustrates one embodiment of a device 10 for inspecting an object 12 using Barkhausen noise generated by the object 12 under inspection. The object 12 is made of ferromagnetic material or comprises a ferromagnetic material. The inspection device 10 includes a magnetic field sensor 14 which includes at least a transceiver solenoid or coil 16, a powering unit 18 for powering the magnetic field sensor 14 and a detection unit 20 for collecting an electrical signal generated by the magnetic field sensor 14. The powering unit 18 is electrically connected to the transceiver coil 16 via at least one electrical connection 22 for powering the transceiver coil 16, i.e. for providing an electrical signal to the transceiver coil 16. The detection unit 20 is also electrically connected to the transceiver coil 16 via at least one electrical connection 24 so as to receive an electrical signal generated by the transceiver coil 16.

In one embodiment, the transceiver coil 16 is configured for concurrently emitting an excitation magnetic field for inspecting the object 12 and detecting an induced magnetic field propagating from the object 12. When transceiver coil 16 is being driven by the powering unit 22, the excitation field generated by the transceiver coil 16 propagates within the object 12 and the transceiver coil 16 concurrently detects the induced magnetic field coming from the object 12 and resulting from the propagation of the excitation magnetic field therein. The induced magnetic field comprises the Barkhausen noise to be measured. The transceiver coil 16 then converts the detected induced magnetic field into a detection electrical signal which is transmitted to the detection unit 20.

In another embodiment, the transceiver coil 16 is configured for being operated in two modes of operation: an emission mode during which it generates an excitation magnetic field for inspecting the object 12, and a detection mode during which it detects an induced magnetic field coming from the object 12. When operated in the emission mode, the transceiver coil 16 converts the electrical signal received from the powering unit 18 into the excitation magnetic field which propagates within the object 12. When operated in the detection mode, the transceiver coil 16 detects the induced magnetic field coming from the object 12 and resulting from the propagation of the inspection magnetic fields therein. The induced magnetic field comprises the Barkhausen noise to be measured. The transceiver coil 16 converts the detected induced magnetic field into a detection electrical signal which is transmitted to the detection unit 20.

The detection unit 20 reads the magnetic field emitted by the object 12, i.e. it collects the electrical signal generated by the outputted by the transceiver coil 16. The detection unit 20 further processes the electrical signal outputted by the transceiver coil 16 and outputs an output signal. The output signal is transmitted to data analysis unit provided with at least a processing unit, a memory and communication means. The data analysis unit converts the received output signal into a digital signal and determines the Barkhausen noise from the converted signal.

In one embodiment, the electrical signal generated by the powering unit 18 is configured for providing the transceiver coil 16 with an adequate voltage for allowing the transceiver coil 16 to generate an inspection magnetic field within the object 12. The electrical signal comprises an AC voltage to be applied to the transceiver coil 16 for generating the excitation magnetic field. For example, the AC voltage may have a sinusoidal shape, a triangular shape, etc.

In an embodiment in which the transceiver coil 16 is operates in two modes of operation, the transceiver coil 16 sequentially operates in the emission mode and subsequently in the detection mode. In this case, the electrical signal generated by the powering unit 18 comprises two phases, i.e. an excitation phase and a detection phase During the excitation phase, the electrical signal comprises an AC voltage to be applied to the transceiver coil 16 for generating the excitation magnetic field. During the detection phase, the electrical signal can be configured so that the transceiver coil 16 emits no magnetic field. For example, during the detection phase, the voltage of the electrical signal applied to the transceiver coil 16 may be substantially equal to zero so that no magnetic field is generated by the transceiver coil 16 when the detection phase of the electrical signal is provided to the transceiver coil 16. Alternatively a non-zero voltage may be applied to the transceiver coil 16 during the detection phase.

It should be understood that, in operation, the transceiver coil 16 is positioned adjacent to the surface of the object 12 to be inspected at a distance therefrom which is adequate to allow the generated excitation magnetic field to penetrate into the object 12.

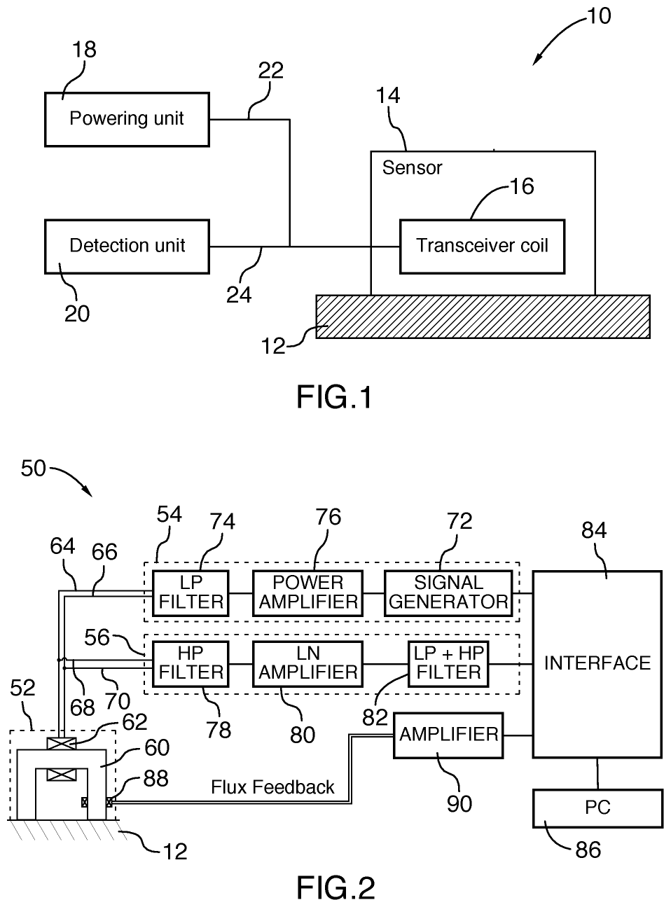

FIG. 2 illustrates one embodiment of a system 50 for inspecting the object 12 using Barkhausen noise generated by the object 12 under inspection. The system 50 includes a sensing unit 52, a powering unit 54 and a detection unit 56. The powering unit 54 is used for powering the sensing unit 52, i.e. for providing the sensing unit 52 with an electrical signal configured for allowing the sensing unit to generate an excitation magnetic field within the object 12. The detection unit 56 is configured for reading the induced magnetic field generated by the object 12 in response to the excitation magnetic field generated by the sensing unit 52.

In the illustrated embodiment, the sensing unit comprises a C-shaped core 60 and a transceiver coil 62 wound around the central portion of the C-shaped core 60. It should be understood that the core 60 is made of a ferromagnetic material such as ferrite or ferritic steel. The transceiver coil 62 is electrically connected to the powering unit 54 via two electrical conductors 64 and 66. The detection unit 56 is also electrically connected to the transceiver coil 62. More particularly, a first conductor 68 electrically connects the detection unit 56 to the conductor 64 and a second conductor 70 electrically connects the detection unit 56 to the conductor 66.

In the illustrated embodiment, the powering unit 54 comprises at least a signal generator 72 configured for generating the electrical signal provided to the transceiver coil 62. As described above and in one embodiment, the electrical signal generated by the signal generator 72 may include an emission phase for allowing the transceiver coil 62 to generate the excitation magnetic field and a detection phase during which the transceiver coil 62 acts as magnetic field sensor for detecting the induced magnetic field emitted by the object 12 and being indicative of the Barkhausen noise. The powering unit 54 further includes a low-pass filter 74 to allow the electrical signal generated by the signal generator 72 to propagate therethrough and prevent the electrical signal generated by the transceiver coil 62 to propagate therethrough in order to electrically protect the signal generator 72.

In one embodiment, the powering unit 54 further includes an amplifier 76 connected between the signal generator 72 and the low-pass filter 74 for amplifying the electrical signal generated by the signal generator 72.

In the illustrated embodiment, the detection unit 56 includes at least a high-pass filter 78 configured for allowing the electrical signal generated by the transceiver coil 62 to propagate therethrough while preventing the electrical signal generated by the powering unit 54 to propagate therethrough. The detection unit 56 may further comprise an amplifier 80 for amplifying the filtered electrical signal outputted by the high-pass filter 78, and a further filter unit 82 which is configured for filtering the amplified electrical signal outputted by the amplifier 80. In one embodiment, the filter unit 82 may comprise at least one low-pass filter and/or at least one high-pass filter. In this case, the low-pass filter contained in the filter unit 82 is introduced to the system with a knee frequency below Nyquist frequency, and the high-pass filter contained in the filter unit 82 ensures that no electrical signal generated by the signal generator 72 may reach the interface 84, so that the measured signal does not reach dynamic range limits of the analog-to-digital converter contained in the interface 84.

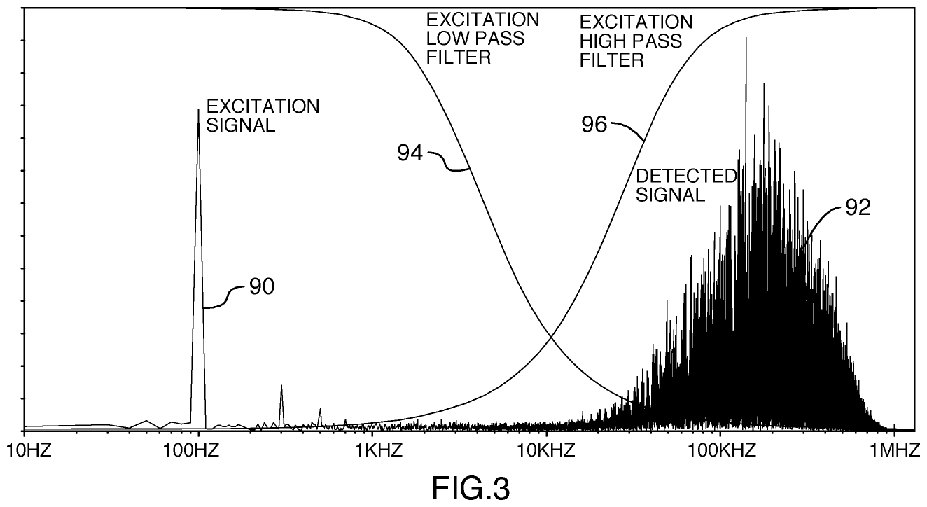

FIG. 3 shows a graph representing an exemplary excitation AC electrical signal 90 that may be generated by the signal generator 72, an exemplary detected electrical signal 92 that may be generated by the transceiver coil 62. In this example, the exemplary excitation electrical signal has a central frequency of about 100 Hz while the exemplary detected electrical signal has a central frequency of about 200 kHz. The graph further illustrates an exemplary bandwidth 94 for the low-pass filter 74 and an exemplary bandwidth 96 for the high-pass filter 78. The exemplary bandwidth 94 of the low-pass filter is chosen so that the exemplary excitation electrical signal 90 may propagate through the low-pass filter 74 while blocking the exemplary detected electrical signal 92. The exemplary bandwidth 96 of the high-pass filter 78 is chosen so that the exemplary detected electrical signal 92 may propagate through the high-pass filter 78 while blocking the exemplary excitation electrical signal 90.

The system 50 further includes the interface 84 comprising at least a processing unit, a memory, communication means and an analog-to-digital converter circuit for converting analog electrical signals into digital signals. The processing unit of the interface 84 is configured for processing the digital signals outputted by the analog-to-digital converter circuit.

The interface 84 is configured for controlling the signal generator 72 and converting the electrical signal coming from the filter unit 82 into a digital signal. It should be understood that the digital signal is indicative of the Barkhausen noise contained in the magnetic field generated by the object 12. The interface 84 is connected to a computer machine 86 also provided with at least a processor, a memory and communication means. The computer machine 86 is configured for extracting the Barkhausen noise from the digital signal and may further be configured for inputting the shape of the electrical signal to be generated by the signal generator 72.

In one embodiment, the system 50 further includes a flux feedback loop formed of a further solenoid or coil 88 and an optional amplifier 90. The coil 88 is wound around one of the two legs of the C-shaped core 60 and is configured for measuring the magnetic field generated by the transceiver coil 60. The coil 88 outputs an electrical signal which is indicative of the magnetic field generated by the transceiver coil 62. The electrical signal outputted by the coil 88 is optionally amplified by the amplifier 90 before being collected by the interface 84. The interface 84 converts the electrical signal coming from the coil 88, via the amplifier 90 or not, into a further digital signal and the further digital signal is transmitted to the computer machine 86. In this case, the computer machine 86 may be configured to set characteristics of the electrical signal to be generated by the signal generator 72 as a function of the further digital signal which is indicative of the magnetic field detected by the coil 8, i.e. based on the excitation magnetic field generated by the transceiver coil 62.

In operation, the signal generator 72 generates an electrical signal which is amplified by the amplifier 76 before propagating through the low-pass filter 74. Then the electrical signal propagates along the conductor 64 and 66. A first part of the electrical signal propagates up to the transceiver coil 62 and a second part propagates up to the high-pass filter 78 where it is blocked and prevented from propagating up to the amplifier 80.

An AC voltage is then applied to the transceiver coil 62 which in turn generates an excitation magnetic field. The excitation magnetic field propagates in the object 12 which in turn emits an induced magnetic field which is indicative of the Barkhausen noise generated within the object 12.

The transceiver coil 62 then detects the induced magnetic field emitted by the object 12 and converts the detected induced magnetic field into an electrical signal of which a first part propagates up the high-pass filter 78 and a second part propagates up to the low-pass filter 74. The low-pass filter 74 block the second part of the electrical signal generated by the transceiver coil 62 and prevents it from reaching the signal generator 72. The first part of the electrical signal propagates through the high-pass filter 78 before being amplified by the amplifier 80 and filtered by the filter unit 82. The resulting electrical signal is converted into an analog signal by the interface 84 and the resulting digital signal is transmitted to the computer machine for analysis and determination of the Barkhausen noise.

In one embodiment and as described above, the emission of the excitation magnetic field and the detection of the induced magnetic field are performed concurrently by the transceiver coil 62.

In another embodiment, the electrical signal generated by the signal generator 72 comprises an emission phase and a detection phase. In this case, the AC voltage is applied to the transceiver coil 62 during the emission phase for generating the excitation magnetic field. During the detection phase of the electrical signal, no excitation magnetic field is emitted and the transceiver coil 62 operates as a magnetic field sensor for detecting the induced magnetic field coming from the object 12.

In an embodiment provided with the further coil 88, the excitation magnetic field generated by the transceiver coil 62 is detected by the further coil 88 and converted into a feedback electrical signal by the coil 88. The feedback electrical signal is amplified by the amplifier 90 before being converted into a feedback digital signal which is transmitted to the computer machine 86. As described above, the computer machine 86 may use the feedback signal to control the generation of the electrical signal by the signal generator 72 using a feedback loop method for example.

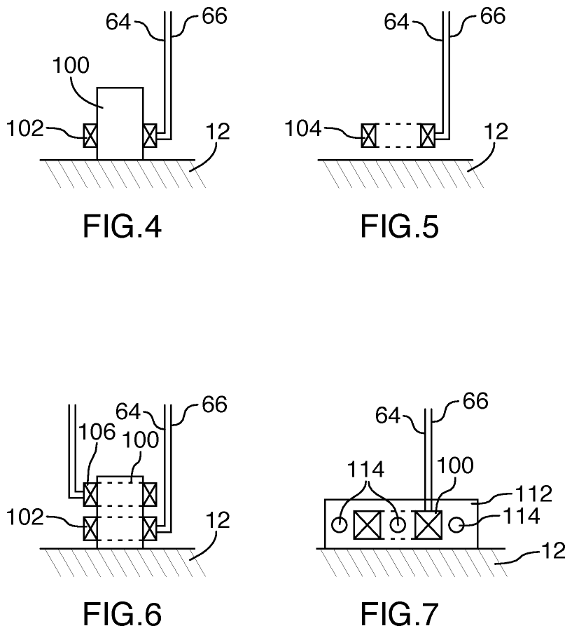

While in the embodiment illustrated in FIG. 2, the transceiver coil 62 is secured around a C-shaped core 60, it should be understood that the core may be provided with another adequate shape or may even be omitted. For example, FIG. 4 illustrates a cylindrical core 100 around which a transceiver coil 102 is wound. When in operation, the core 102 is positioned relative to the object 12 so that its longitudinal axis be substantially orthogonal to the surface of the object 12. FIG. 5 illustrates an embodiment which includes only a transceiver coil 104 and no core. FIG. 6 illustrates the core 100 of FIG. 3 to which a further coil 106 has been secured. One of the coils 102 and 106 may be used for measuring the magnetic field generated by the other coil 102, 106 acting as a transceiver coil or the magnetic field emitted by the object 12. FIG. 7 illustrates an embodiment in which a transceiver coil 110 is embedded into a body 112. The body 112 is provided with at least one aperture or channel 114 extending therethrough and configured for receiving a cooling fluid. The body 112 may be made of non-ferromagnetic electrically insulating material such as plastic (polytetrafluoroethylene, polyethylene terephthalate, acrylonitrile butadiene styrene, etc.) or ceramic material such as aluminum oxide . In one embodiment, the channels 114 may be omitted.

It should be understood that the device 10 may be provided with a casing, housing or enclosure in which at least the transceiver coil and the core, if any, are housed. In one embodiment, the powering unit and/or the detection may also be enclosed within the casing.

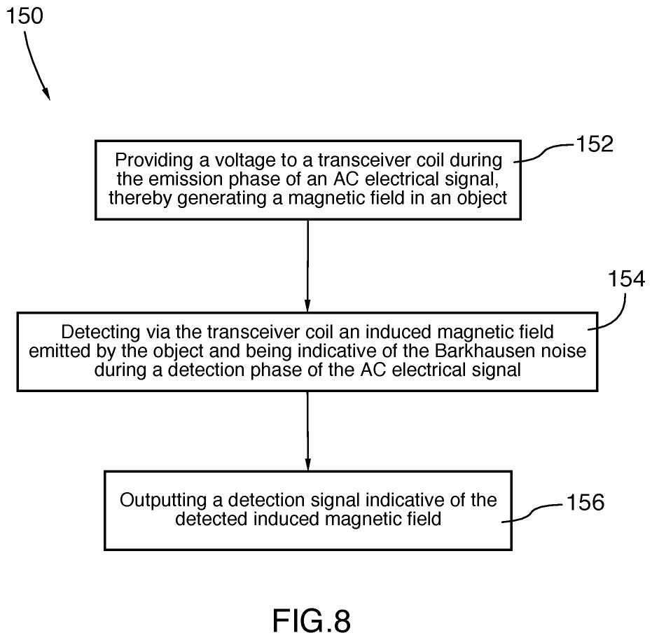

FIG. 8 illustrates one embodiment of a method 150 for inspecting an object made of ferromagnetic material using Barkhausen noise measurement. The method 150 may be performed using the device 10 or the system 50 described above.

At step 152, an AC voltage of an electrical signal generated by a signal generator is provided to a transceiver coil positioned adjacent to the surface of the object to be inspected. The application of the AC voltage causes the transceiver coil to generate an excitation magnetic field which propagates into the object under inspection. The object then generates an induced magnetic field indicative of the Barkhausen noise.

At step 154, the transceiver coil detects the induced magnetic field emitted by the object. The transceiver coil then generates an electrical signal indicative of the detected induced magnetic field, and therefore indicative of the Barkhausen noise.

At step 156, the electrical signal generated by the transceiver coil at step 154 is outputted.

In one embodiment, the step 152 of emitting the excitation magnetic field and the step 154 of detecting the induced magnetic field are performed substantially concurrently.

In another embodiment, the step 152 of emitting the excitation magnetic field and the step 154 of detecting the induced magnetic field are performed iteratively. In this case, the electrical signal generated by the signal generator comprises an emission phase during which the electrical signal comprises the AC voltage and the transceiver coil emits the excitation magnetic field, and a detection phase during which the transceiver coil operates as a magnetic field sensor to detect the induced magnetic field coming from the object under inspection. In one embodiment, no voltage is applied to the transceiver coil during the detection phase.

In one embodiment, the method 150 further includes a step of protecting the signal generator used for generating the electrical signal for powering the transceiver coil from the electrical signal generated by the transceiver coil. For example, the electrical signal generated by the transceiver coil may be filtered by a low pass filter.

In one embodiment, the electrical signal generated by the signal generator may be amplified before being provided to the transceiver coil.

In one embodiment, the method 150 may further comprise a step of filtering the electrical signal generated by the transceiver coil using a high-pass filter for example. In one embodiment, the high-pass filtered electrical signal may be amplified and the amplified electrical signal may be further filtered using at least one of an output high pass filter and an output low pass filter.

In one embodiment, the method 150 may further comprise a step of measuring the excitation magnetic field generated by the transceiver coil. The measurement of the excitation magnetic field may be performed using an additional coil or solenoid.

In one embodiment, the method 150 may further comprise a step of controlling the electrical signal provided to the transceiver coil based on the measured excitation magnetic field. For example, characteristics of the electrical signal such as its amplitude may be chosen as a function of the measured excitation magnetic field.

In one embodiment, the purpose of the present method and device is to help inspect of the quality of ferromagnetic components. For example, the present method and device may be useful when trying to measure objects provided with complex geometries, such as curved surfaces or geometries provided with relatively small holes.

The embodiments of the invention described above are intended to be exemplary only. The scope of the invention is therefore intended to be limited solely by the scope of the appended claims.

I/we claim:

1. A Barkhausen noise sensing device for inspecting an object made of ferromagnetic material, comprising:
a transceiver coil configured for generating an excitation magnetic field within the object and detecting a Barkhausen noise emitted by the object;
a powering unit connected to the transceiver coil and connectable to a power source, the powering unit being configured for providing the transceiver coil with an Alternating Current (AC) electrical signal to generate the excitation magnetic field and
a detection unit connected to the transceiver coil for reading an induced magnetic field emitted by the object in response to the excitation magnetic field and being indicative of the Barkhausen noise, the detection unit being configured for outputting a detection signal indicative of the detected induced magnetic field.

2. The Barkhausen noise sensing device of claim 1, wherein the transceiver coil is configured for concurrently emitting the excitation magnetic field and detecting the induced magnetic field.

3. The Barkhausen noise sensing device of claim 1, wherein the AC electrical signal includes an emission phase and a detection phase, the excitation magnetic field being generated by the transceiver coil during the emission phase and the Barkhausen noise being detected during the detection phase.

4. The Barkhausen noise sensing device of claim 1, further includes a coil core having the transceiver coil wound therearound.

5. The Barkhausen noise sensing device of claim 4, wherein the coil core has one of a U-shape, a C-shape and a cylindrical shape.

6. The Barkhausen noise sensing device of claim 4, wherein the transceiver coil is embedded into the coil core;

7. The Barkhausen noise sensing device of claim 6, wherein the coil core includes at least one aperture extending therethrough for receiving therein a cooling medium.

8. The Barkhausen noise sensing device of claim 1, wherein the powering unit includes a signal generator for generating said AC electrical signal.

9. The Barkhausen noise sensing device of claim 8, the powering unit further includes an input low-pass filter for protecting the signal generator from a noise electrical signal generated by the transceiver coil upon detection of the induced magnetic field.

10. The Barkhausen noise sensing device of claim 8, wherein the powering unit further includes an input power amplifier for amplifying the AC electrical signal generated by the signal generator.

11. The Barkhausen noise sensing device of claim 1, wherein the detection unit includes a noise high pass filter for blocking the AC electrical signal.

12. The Barkhausen noise sensing device of claim 11, wherein the detection unit further includes a noise amplifier for amplifying a filtered signal outputted by the noise high pass filter.

13. The Barkhausen noise sensing device of claim 12, wherein the detection unit further includes at least one of an output high pass filter and an output low pass filter for filtering an amplifier signal outputted by the noise amplifier.

14. The Barkhausen noise sensing device of claim 1, further includes a control flux sensor for measuring the excitation magnetic field generated by the transceiver coil.

15. The Barkhausen noise sensing device of claim 14, wherein the control flux sensor includes a control flux coil.

16. The Barkhausen noise sensing device of claim 14, further includes a processing unit for controlling the AC electrical signal generated by the powering unit based on the excitation magnetic field measured by the control flux sensor.

17. The Barkhausen noise sensing device of claim 1, further includes a casing for receiving therein at least the transceiver coil, the powering unit and the detection unit.

18. A method for inspecting an object made of ferromagnetic material using Barkhausen noise measurement, comprising:
providing a voltage of an Alternating Current (AC) electrical signal to a transceiver coil positioned adjacent to the object, thereby causing the transceiver coil to emit an excitation magnetic field within the object;
detecting via the transceiver coil an induced magnetic field emitted by the object in response to the excitation magnetic field and being indicative of the Barkhausen noise; and
outputting a detection signal indicative of the detected induced magnetic field.

19. The method of claim 18, wherein said providing the voltage to the transceiver coil and said detecting the induced magnetic field are performed concurrently.

20. The method of claim 18, wherein said providing the voltage to the transceiver coil and said detecting the induced magnetic field are performed iteratively.

21. The method of claim 18, further including the step of protecting a signal generator used for generating the AC electrical signal from a noise electrical signal generated by the transceiver coil upon detection of the induced magnetic field using an input low pass filter.

22. The method of claim 20, further including the step of amplifying the AC electrical signal before said providing the voltage to the transceiver coil.

23. The method of claim 20, further including the step of protecting a detection unit from the AC electrical signal using a noise high pass filter.

24. The method of claim 23, further including the step of amplifying a filtered signal outputted by the noise high pass filter, thereby obtaining an amplified signal.

25. The method of claim 24, further including the step of filtering the amplified signal using at least one of an output high pass filter and an output low pass filter.

26. The method of claim 20, further including the step of measuring the excitation magnetic field generated by the transceiver coil.

27. The method of claim 26, wherein said measuring the excitation magnetic field is performed using a control flux coil.

28. The method of claim 26, further including the step of controlling the AC electrical signal based on the measured excitation magnetic field.
